(19) United States
(12) Patent Application Publication
(10) Pub. No.: US 2026/0074161 A1
(43) Pub. Date: Mar. 12, 2026

(54) PLASMA TREATMENT APPARATUS AND MANUFACTURING METHOD OF SEMICONDUCTOR DEVICE

(71) Applicant: Kioxia Corporation, Tokyo (JP)

(72) Inventors: Junichi HAMAGUCHI, Kuwana Mie (JP); Yuuko KAWAGUCHI, Yokkaichi Mie (JP); Masayuki FUKUMOTO, Kuwana Mie (JP)

(73) Assignee: Kioxia Corporation, Tokyo (JP)

(21) Appl. No.: 19/073,124

(22) Filed: Mar. 7, 2025

(30) Foreign Application Priority Data
Sep. 11, 2024 (JP) 2024-157542

(51) Int. Cl. H01J 37/32

(52) U.S. Cl. CPC H01J 37/32642; H01J 2237/334

(57) ABSTRACT

According to one embodiment, a plasma treatment apparatus includes a treatment chamber for applying treatment to a substrate of a semiconductor device, a stage on which the substrate is placed, a plasma generator, a first annular member, and a first moving mechanism. The first annular member is disposed around the substrate placed on the stage. The first annular member is divided into first annular member pieces arranged in a circumferential direction. The first moving mechanism moves the first annular member to a position at which the first annular member is concentric with the substrate. The first annular member is moved by moving each of the first annular member pieces in a radial direction of the substrate. The first moving mechanism relatively changes a horizontal distance between an end of the substrate and an inner end of the first annular member.

### CROSS-REFERENCE TO RELATED APPLICATIONS

This application is based upon and claims the benefit of priority from Japanese Patent Application No. 2024-157542, filed on Sep. 11, 2024, the entire contents of which are incorporated herein by reference.

### FIELD

Embodiments described herein relate generally to a plasma treatment apparatus and a manufacturing method of a semiconductor device.

### BACKGROUND

When plasma treatment is applied to a substrate in a process for manufacturing a semiconductor device, it is required that the treatment should be uniform across the substrate surface. If the plasma treatment is non-uniform between the central part and outer periphery of the substrate, it may cause defects in the semiconductor device formed on the outer periphery.

### BRIEF DESCRIPTION OF THE DRAWINGS

FIG. 1 is a diagram schematically illustrating an example of the overall configuration of a plasma treatment apparatus according to a first embodiment;

FIG. 2Aa to 2Bb are diagrams illustrating the detailed configuration of the cover ring provided in the plasma treatment apparatus according to the first embodiment;

FIGS. 3A and 3B are diagrams explaining the procedure of first movement control in the plasma treatment apparatus according to the first embodiment;

FIG. 4 is a diagram explaining the in-plane uniformity of the sputtering process with and without the execution of the first movement control according to the first embodiment;

FIG. 5 is a flowchart illustrating an example of a procedure of the sputtering process in the plasma treatment apparatus according to the first embodiment;

FIG. 6 is a diagram illustrating an example of the shape of an end of a cover ring piece provided in the plasma treatment apparatus according to a variation of the first embodiment;

FIG. 7 is a cross-sectional view schematically illustrating an example of the overall configuration of a plasma treatment apparatus according to a second embodiment;

FIGS. 8A and 8B are top views illustrating the detailed configuration of a top ring provided in the plasma treatment apparatus according to the second embodiment;

FIGS. 9A and 9B are diagrams explaining the procedure of a first movement control in the plasma treatment apparatus according to the second embodiment;

FIGS. 10A and 10B are diagrams explaining the procedure of a second movement control in the plasma treatment apparatus according to the second embodiment; and

FIG. 11 is a flowchart illustrating an example of an etching process procedure in the plasma treatment apparatus according to the second embodiment.

### DETAILED DESCRIPTION

In general, according to one embodiment, a plasma treatment apparatus includes a treatment chamber, a stage, a plasma generator, a first annular member, and a first moving mechanism. The treatment chamber is capable of processing a substrate. The substrate is to be placed on the stage. The stage is provided inside the treatment chamber. The plasma generator is configured to generate plasma above the stage on which the substrate is placed. The first annular member is disposed around the substrate placed on the stage. The first annular member is divided into first annular member pieces that are arranged in a circumferential direction. The first moving mechanism is configured to move the first annular member to a position at which the first annular member is concentric with the substrate. The first annular member is moved by moving each of the first annular member pieces in a radial direction of the substrate. The first moving mechanism is configured to relatively change a horizontal distance between an end of the substrate and an inner end of the first annular member.

Exemplary embodiments of a plasma treatment apparatus will be described below in detail with reference to the accompanying drawings. It should be noted that the present invention is not limited to the following embodiments. In addition, the components in the following embodiments include those that a person skilled in the art would easily imagine or that are substantially the same.

### First Embodiment

### Configuration Example of Plasma Treatment Apparatus

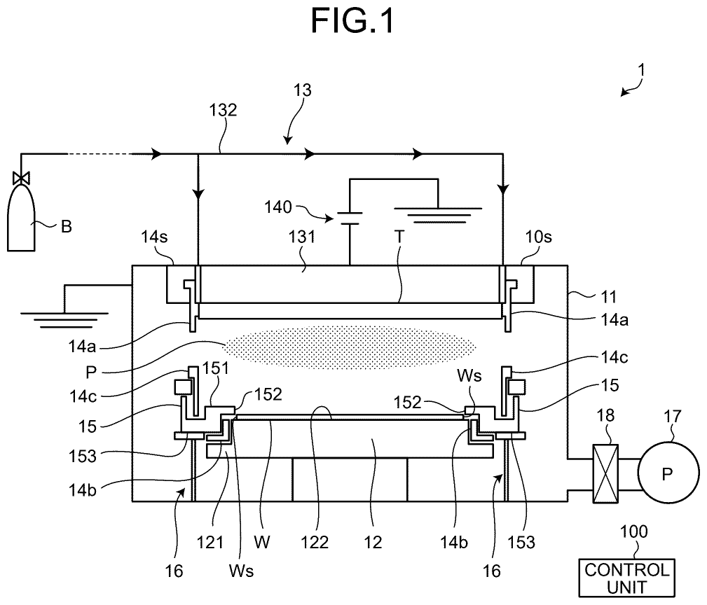

FIG. 1 is a diagram schematically illustrating an example of the overall configuration of a plasma treatment apparatus 1 according to a first embodiment.

A device layer, such as a three-dimensional non-volatile memory, or the like, is formed on a top surface of a substrate W of a semiconductor device, which is to be processed by the plasma treatment apparatus 1 of the first embodiment. The stress of each layer formed in the manufacturing process of the device layer causes warping in the substrate W. In order to correct the warping of the substrate W, a predetermined film is formed on a back surface of the substrate W by sputtering process. The plasma treatment apparatus 1 of the first embodiment is configured as a sputtering device for forming a predetermined film on the substrate W. The sputtering process is an example of plasma treatment.

As illustrated in FIG. 1, the plasma treatment apparatus 1 includes a treatment chamber 11 and a control unit 100 (an example of a control device).

The treatment chamber 11 is a housing configured to be able to accommodate the substrate W to be processed.

A stage 12 is provided at the bottom inside the treatment chamber 11. The stage 12 includes a placement surface 122 on which a substrate W can be placed. The substrate W that has been loaded into the treatment chamber 11 is placed on the placement surface 122 with its back surface facing upward. In addition, the stage 12 includes a flange-shaped part 121 on its periphery. The stage 12 functions as an anode electrode.

A plasma generator 13 that is configured to generate plasma P is provided above the stage 12. The plasma generator 13 includes a cathode electrode 131 and a gas supply pipe 132.

The cathode electrode 131 is a circular plate-shaped member disposed at an upper position in the treatment chamber 11, opposite the stage 12.

The gas supply pipe 132 is connected to the upper surface of the treatment chamber 11. More specifically, the upstream end of the gas supply pipe 132 is connected to a cylinder B, and the downstream end thereof is connected to the upper surface of the treatment chamber 11. The gas supplied from the cylinder B is introduced into the treatment chamber 11 from the upper surface of the treatment chamber 11. The gas introduced into the treatment chamber 11 is, for example, N2 gas, Ar gas, etc.

In addition, a pump 17 is connected to the treatment chamber 11 via a gate valve 18. The gate valve 18 and the pump 17 are disposed, for example, diagonally below the stage 12 on which the substrate W is placed. By opening and closing the gate valve 18, evacuation of the atmosphere in the treatment chamber 11 by the pump 17 can be started and stopped.

When performing sputtering process, first, the substrate W is placed on the placement surface 122 of the stage 12 with its back surface facing upward. The pump 17 is operated to open the gate valve 18, and the atmosphere in the treatment chamber 11 is evacuated. Then, gas is supplied from the cylinder B into the treatment chamber 11. When a high voltage is applied by the high-voltage power supply 140, plasma P is generated in the inner space of the treatment chamber 11.

The cathode electrode 131 holds a target member T whose main component is, for example, silicon (Si). A high-voltage power supply 140 is connected to the target member T. When plasma P is generated in the inner space of the treatment chamber 11, positive ions in the plasma P collide with the target member T. Sputtering particles emitted from the target member T are deposited on the substrate W. Accordingly, a predetermined film is formed on the back surface of the substrate W. The predetermined film is, for example, a silicon nitride film (SiN film).

In addition, at this time, the sputtered particles are deposited not only on the substrate W, but also on the anti-deposition plates 14a to 14c, the cover ring 15, and the like, which will be described later. When the sputtering process is repeatedly performed, the target member T is consumed and a sputtered particle layer having a layer thickness corresponding to the consumed amount of the target member T is formed on the anti-deposition plates 14a to 14c and the cover ring 15.

Conventionally, the target life is used as an index representing the consumed amount of the target member T. The target life indicates the consumed amount relative to the maximum usable amount of the target member T. The target life is calculated based on the accumulated amount of power since the target member T was replaced with a new one. For example, when the target life is in an early stage, the consumed amount of the target member T is small. That is, the layer thickness of the sputtered particle layer formed on the anti-deposition plates 14a to 14c and the cover ring 15 is small. On the other hand, for example, when the target life is in a final stage, the consumed amount of the target member T is large. That is, the layer thickness of the sputtered particle layer formed on the anti-deposition plates 14a to 14c and the cover ring 15 is large. When the target life passes the final stage and exceeds a predetermined threshold value for the usable amount, the target member T is replaced with a new one. The target life of the target member T is managed by the control unit 100.

The cover ring 15 is an annular member that is disposed around the substrate W placed on the placement surface 122. The base material of the cover ring 15 is made of steel special use stainless steel (SUS) or the like. It should be noted that the material of the cover ring 15 is not limited to SUS. The cover ring 15 prevents sputtered particles emitted from the target member T from adhering to each component around the substrate W. The cover ring 15 is an example of a first annular member.

The cover ring 15 includes a main surface 151 extending in the surface direction of the substrate W, and an end surface 152 extending downward from the end of the main surface 151 on the substrate W side. The end surface 152 of the cover ring 15 overlaps in the vertical direction with the end Ws of the substrate W. This suppresses sputtered particles scattering from the target member T toward the substrate W and particles present in the treatment chamber 11 from wrapping around to the formation surface side of the device layer of the substrate W through the end Ws of the substrate W.

In addition, the cover ring 15 is divided in the circumferential direction. Although details will be described later, each cover ring piece is connected to a first moving mechanism 16 at its lower surface 153. The lower end of the first moving mechanism 16 is supported by the lower surface of the treatment chamber 11. The first moving mechanism 16 moves each cover ring piece in the radial direction of the substrate W in accordance with instructions from the control unit 100. This enables the cover ring 15 to move to a position at which the cover ring 15 is concentric with the substrate W.

The anti-deposition plates 14a to 14c prevent sputtered particles emitted from the target member T from adhering to each component inside the treatment chamber 11. The anti-deposition plate 14a is a circular plate-like member attached to an anti-deposition plate support member 14s disposed to surround the cathode electrode 131. The anti-deposition plate 14b and the anti-deposition plate 14c are annular members. The anti-deposition plate 14b is disposed below the cover ring 15. More specifically, the anti-deposition plate 14b is disposed between the upper surface of the flange-shaped part 121 of the stage 12 and the placement surface 122 of the substrate W. In addition, the anti-deposition plate 14c is disposed on the side of the cover ring 15. The anti-deposition plate 14c extends upward from the side of the cover ring 15 along the inner wall of the treatment chamber 11 and is disposed so as to surround the space above the stage 12. It should be noted that it is not necessary that both the anti-deposition plate 14b and the anti-deposition plate 14c are disposed inside the treatment chamber 11, and it is sufficient that at least one of the anti-deposition plate 14b or the anti-deposition plate 14c is disposed inside the treatment chamber 11.

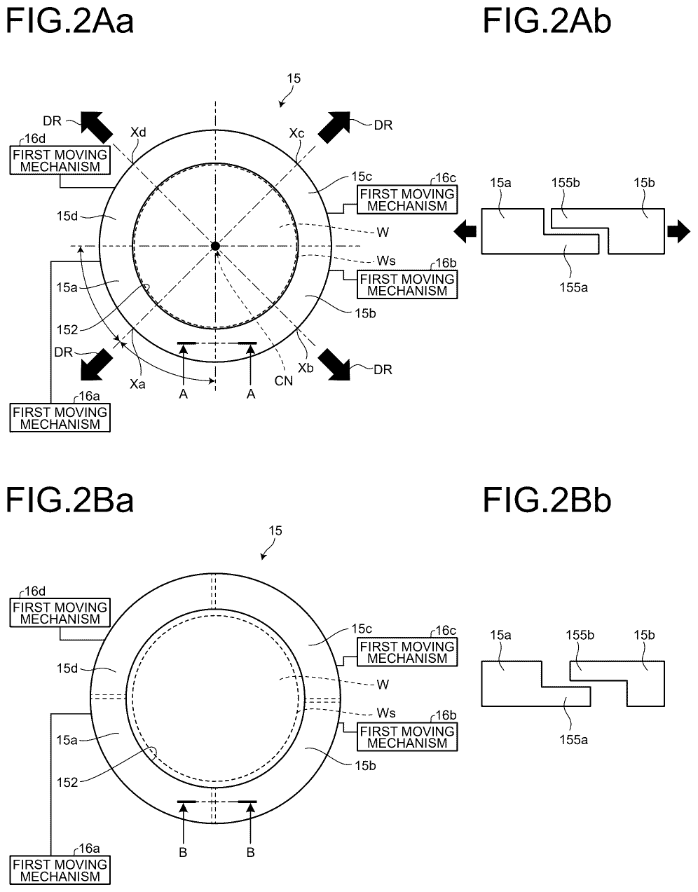

FIG. 2Aa to 2Bb are diagrams illustrating the detailed configuration of the cover ring 15 provided in the plasma treatment apparatus 1 according to the first embodiment.

FIG. 2Aa is a top view illustrating a state where the cover ring 15 is disposed at a reference position. In the present embodiment, the reference position is a position where the end surface 152 of the cover ring 15 vertically overlaps with the end Ws of the substrate W placed on the placement surface 122. On the other hand, FIG. 2Ba is a top view illustrating a state after the cover ring 15 has moved from the reference position to a position at which the cover ring 15 is concentric with the substrate W. In addition, FIG. 2Ab and 2Bb are cross-sectional views taken along line AA in FIG. 2Aa and line BB in FIG. 2Ba, respectively.

As illustrated in FIG. 2Aa, the cover ring 15 is divided into cover ring pieces 15a to 15d that are arranged in the circumferential direction. Each of the cover ring pieces 15a to 15d is in an arc shape. The cover ring pieces 15a to 15d are connected to first moving mechanisms 16a to 16d, respectively. The cover ring pieces 15a to 15d are examples of the first annular member pieces.

The first moving mechanisms 16a to 16d move the cover ring pieces 15a to 15d in the radial direction of the substrate W, respectively. Specifically, if the points obtained by equally dividing the respective outer peripheries of the cover ring pieces 15a to 15d in the circumferential direction are points Xa to Xd, the first moving mechanisms 16a to 16d move the respective cover ring pieces 15a to 15d in a direction connecting the center point CN of the substrate W with respective points Xa to Xd. The direction connecting the center point CN with each of the points Xa to Xd is the radial direction of the substrate W, which is the direction indicated by the arrow DR in FIG. 2Aa. At this time, the radial movement distances of the cover ring pieces 15a to 15d are the same for all the cover ring pieces. Accordingly, as illustrated in FIG. 2Ba, the cover ring 15 moves to a position at which the cover ring 15 is concentric with the substrate W, and the horizontal distance between the end Ws of the substrate W and the end surface 152 of the cover ring 15 changes relatively. The first moving mechanisms 16a to 16d perform the above-mentioned operations in response to instructions from the control unit 100.

In addition, among the cover ring pieces 15a to 15d, the ends of adjacent cover ring pieces in the circumferential direction engage with each other by a labyrinth structure. Specifically, for example, the right end of each of cover ring pieces 15a and 15b illustrated in FIG. 2Ab is defined as one end, and the left end as the other end. The cover ring piece 15a includes a first step part 155a at one end, and the cover ring piece 15b includes a second step part 155b at the other end. The first step part 155a engages with the second step part 156b. That is, the first step part 155a and the second step part 155b overlap with each other in the vertical direction.

Accordingly, even when the cover ring pieces 15a and 15b move in the radial direction, namely, when one end of cover ring piece 15a and the other end of cover ring piece 15b move in a direction in which they are separated, the first step part 155a of the cover ring piece 15a and the second step part 155b of the cover ring piece 15b can be kept overlapping with each other in the vertical direction as illustrated in FIG. 2Bb. As a result, it is possible to suppress the sputtered particles and other particles passing between one end of the cover ring piece 15a and the other end of the cover ring piece 15b and scattering downward.

Returning to FIG. 1, the control unit 100 controls each unit of the plasma treatment apparatus 1. The control unit 100 is configured as a computer equipped with a central processing unit (CPU), a read only memory (ROM), and a random access memory (RAM), and the like, which are not illustrated, and controls the entire plasma treatment apparatus 1. For example, the control unit 100 controls each unit mentioned above to perform sputtering process on the substrate W. In addition, for example, the control unit 100 performs a first movement control for moving the cover ring pieces 15a to 15d in the radial direction by instructing the first moving mechanisms 16a to 16d. When performing the first movement control, the control unit 100 refers to the target life of the target member T. The control unit 100 determines the movement amount of the cover ring pieces 15a to 15d based on the target life.

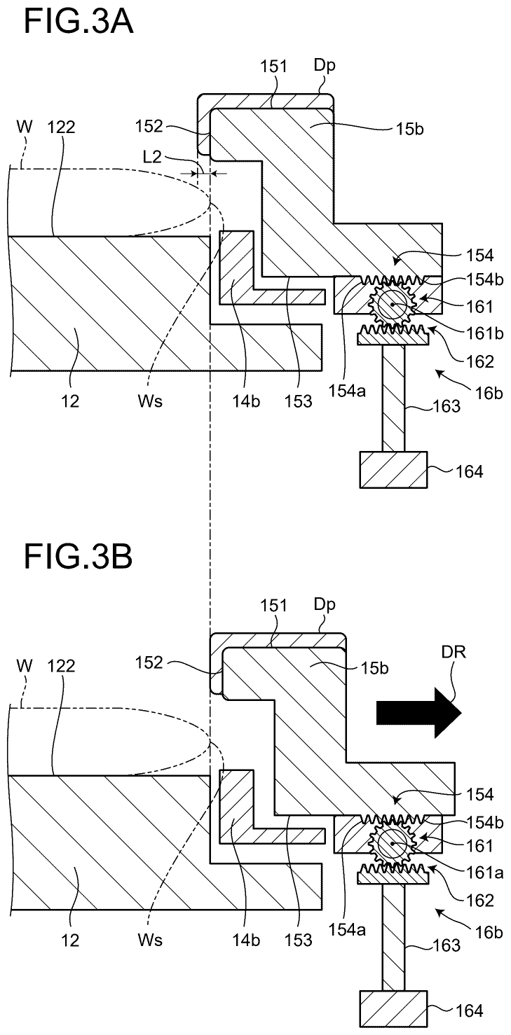

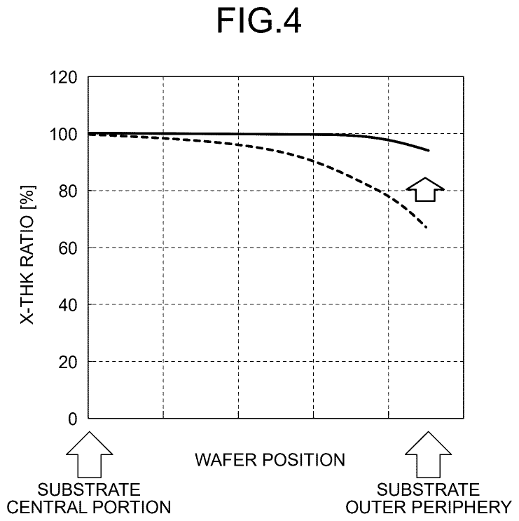

Next, the procedure of the first movement control by the control unit 100 will be described with reference to FIGS. 3A to 3B and FIG. 4.

FIGS. 3A and 3B are diagrams for explaining the procedure of the first movement control in the plasma treatment apparatus 1 according to the first embodiment. In FIGS. 3A and 3B, the procedure of the first movement control executed for the cover ring piece 15b as an example among the cover ring pieces 15a to 15d is explained. FIG. 3A is a cross-sectional view illustrating the state in the vicinity of the cover ring piece 15b disposed in the reference position immediately before the first movement control is executed. FIG. 3B is a cross-sectional view illustrating the state in the vicinity of the cover ring piece 15b immediately after the first movement control is executed. Both FIGS. 3A and 3B illustrate a state where the target life of the target member T is in a final stage and illustrate a state before the substrate W is placed on the placement surface 122.

In addition, FIG. 4 is a diagram for explaining the in-plane uniformity of the sputtering process with and without the execution of the first movement control according to the first embodiment. The horizontal axis of FIG. 4 corresponds to the distance from the central part of the substrate W, and the vertical axis of FIG. 4 corresponds to the film thickness of a predetermined film formed on the substrate W. It should be noted that the film thickness of the predetermined film is indicated as a percentage of the film thickness at a predetermined position in the vicinity of the central part of the substrate W. That is, the closer the vertical axis in FIG. 4 is to 100%, the more it means that the predetermined film is uniformly formed at the central part and outer periphery of the substrate W.

As illustrated in FIG. 3A, when the target life is in a final stage, a sputtered particle layer Dp having a thickness L2, for example, is formed on the main surface 151 and end surface 152 of the cover ring piece 15b.

If sputtering process is performed in a state where the cover ring 15 including such cover ring piece 15b is disposed at the reference position, the film thickness of the predetermined film formed on the outer periphery of the substrate W is significantly reduced, as illustrated by the dotted line in FIG. 4. This is because the sputtered particle layer Dp with thickness L2 formed on the end surface 152 of the cover ring piece 15b covers the upside of the end Ws of the substrate W, and the formation of the predetermined film is hindered in the covered part. If the film thickness on the outer periphery of the substrate W is reduced, the in-plane uniformity is deteriorated, and defects may occur in the semiconductor device. Therefore, it is desirable to form a predetermined film with the same thickness on the outer periphery of the substrate W as on the central part of the substrate W. Thus, it is desirable to perform sputtering process as uniformly as possible between the central part and the outer periphery of the substrate W.

For that reason, the control unit 100 moves the cover ring piece 15b radially outward by an amount equivalent to the thickness L2. Specifically, the control unit 100 first obtains the target life of the target member T, and determines the thickness L2 of the sputtered particle layer Dp based on the obtained target life. A table indicating the correspondence between the target life and the thickness of the sputtered particle layer Dp, which has been created in advance by an operator or the like, is stored in a storage unit (not illustrated) of the control unit 100. The control unit 100 determines the thickness L2 of the sputtered particle layer Dp corresponding to the obtained target life based on the table. The control unit 100 determines the determined thickness L2 as the radial movement amount of the cover ring piece 15b.

For example, when the thickness L2 of the sputtered particle layer Dp is determined to be 0.75 mm, the control unit 100 controls the first moving mechanism 16b to move the cover ring piece 15b outward by 0.75 mm in the radial direction. Accordingly, as illustrated in FIG. 3B, the sputtered particle layer Dp formed on the end surface 152 of the cover ring 15 does not cover the upside of the end Ws of the substrate W. As a result, the uniformity of the sputtering process on the substrate surface is improved, and a decrease in the film thickness of the predetermined film at the outer periphery of the substrate W is suppressed, as illustrated by the solid line in FIG. 4.

It should be noted that the control unit 100 does not necessarily have to calculate the thickness L2 of the sputtered particle layer Dp. For example, a table that defines the relationship between the target life and the target position of the cover ring piece 15b is stored in a storage unit (not illustrated) of the control unit 100. The control unit 100 may determine the target position of the cover ring piece 15b based on the obtained target life and the table, and move the cover ring piece 15b to the determined target position.

Here, the detailed configuration of the first moving mechanism 16 will be described with reference to FIGS. 3A and 3B. A first moving mechanism 16b is connected to the cover ring piece 15b.

As illustrated in FIGS. 3A and 3B, a rack gear 154, which is a spur gear with an infinite diameter, is provided on the lower surface 153 of the cover ring piece 15b.

The first moving mechanism 16b includes a pinion gear 161 that meshes with the rack gear 154, and a bevel gear 162 that meshes with the pinion gear 161 and drives the pinion gear 161. The first moving mechanism 16b further includes a shaft 163 that extends in the vertical direction, and an actuator 164 that is connected to the lower end of the shaft 163. The bevel gear 162 is connected to the upper end of the shaft 163. The actuator 164 rotates the bevel gear 162 by rotating the shaft 163. In addition, the pinion gear 161 is connected to a rotary shaft 161b that extends circumferentially. The pinion gear 161 rotates radially around the rotary shaft 161b due to the rotation of the bevel gear 162.

The rack gear 154 includes protrusions 154a and recesses 154b alternately aligned in a row. The direction in which the protrusions 154a and the recesses 154b are aligned is a direction along the radial direction of the substrate W. With the above-described configuration, the first moving mechanism 16b can move the cover ring piece 15b in a direction along the radial direction of the substrate W, namely, in the direction of the arrow DR in FIG. 3B.

### Manufacturing Method of a Semiconductor Device

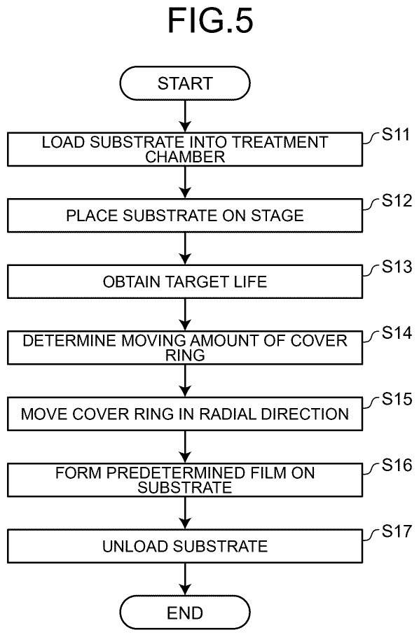

FIG. 5 explains the procedure of the sputtering process as part of the manufacturing method of the semiconductor device of the first embodiment.

FIG. 5 is a flow chart illustrating an example of a procedure of the sputtering process in the plasma treatment apparatus 1 according to the first embodiment. The first movement control mentioned above is performed as part of the sputtering process.

A device layer, such as a three-dimensional non-volatile memory or the like, is formed on the surface of the substrate W to be processed by the plasma treatment apparatus 1 of the first embodiment.

The control unit 100 controls a transport arm (not illustrated) to load the substrate W into the treatment chamber 11 with its back surface facing upward (S11). Then, the control unit 100 controls the transport arm to place the substrate W on the placement surface 122 of the stage 12 (S12). A cover ring 15 is disposed around the substrate W placed on the placement surface 122.

The control unit 100 obtains the target life of the target member T (S13).

The control unit 100 determines the thickness L2 of the sputtered particle layer Dp formed on the cover ring 15 based on the target life, and determines an amount equivalent to the thickness L2 as the radial movement amount of the cover ring 15 (S14).

The control unit 100 controls the first moving mechanisms 16a to 16d in accordance with the determined movement amount, and moves the cover ring pieces 15a to 15d in the radial direction of the substrate W. Accordingly, the cover ring 15 moves to a position at which the cover ring 15 is concentric with the substrate W, and the horizontal distance between the end Ws of the substrate W and the inner end surface 152 of the cover ring pieces 15a to 15d is changed (S15). It should be noted that the processing of S13 and S14 may be performed at any timing before the processing of S15 is started.

The control unit 100 controls the plasma generator 13 to generate plasma P and form a predetermined film on the substrate W (S16).

When the formation of the predetermined film is completed, the control unit 100 controls the transport arm (not illustrated) to unload the substrate W from the treatment chamber 11 (S17). As described above, the sputtering process of the first embodiment is completed.

### Generalization

The plasma treatment apparatus 1 of the first embodiment includes: a stage 12 on which a substrate W can be placed; a plasma generator 13 that generates plasma; a cover ring 15 that is divided into first annular member pieces arranged around the substrate W in the circumferential direction; and a first moving mechanism 16. The first moving mechanism 16 moves the cover ring 15 to a position at which the cover ring 15 is concentric with the substrate W by moving each of the first annular member pieces in a radial direction of the substrate W, and relatively changes a horizontal distance between an end Ws of the substrate W and an inner end surface 152 of the cover ring 15.

Accordingly, even if a sputtered particle layer Dp is formed, for example, on the inner end surface 152 of the cover ring 15 in the sputtering device, by moving the cover ring 15 to a position at which the cover ring 15 is concentric with the substrate W, it is possible to avoid the sputtered particle layer Dp covering the upside of the end Ws of the substrate W. As a result, the sputtering process can be performed more uniformly from the central part to the outer periphery of the substrate W.

In addition, the cover ring 15 is divided into four cover ring pieces 15a to 15d, and the ends of adjacent cover ring pieces in the circumferential direction among the four cover ring pieces 15a to 15d are engaged with each other by a labyrinth structure.

Accordingly, the ends of adjacent cover ring pieces remain overlapped in the vertical direction even when the four cover ring pieces 15a to 15d are moved outward in the radial direction of the substrate W. As a result, it is possible to suppress the sputtered particles generated in the treatment chamber 11 scattering downward through between the ends of adjacent cover ring pieces.

### Variations

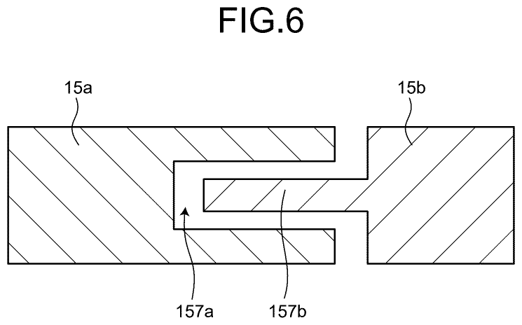

A variation of the first embodiment will be described with reference to FIG. 6. In the plasma treatment apparatus of the variation, the shape of the ends of the four cover ring pieces 15a to 15d differs from that of the first embodiment mentioned above. It should be noted that in the following, the same components as those in the above-mentioned embodiment will be given the same reference numerals, and the description thereof may be omitted.

FIG. 6 is a diagram illustrating an example of the shape of the ends of the cover ring pieces 15a to 15d included in the plasma treatment apparatus according to the variation of the first embodiment. FIG. 6 is a diagram corresponding to FIG. 2Ab.

As illustrated in FIG. 6, cover ring piece 15a includes a recess 157a at one end, and cover ring piece 15b includes a protrusion 157b at the other end. The recess 157a of cover ring piece 15a and the protrusion 157b of cover ring piece 15b overlap with each other in the vertical direction.

Accordingly, even when the cover ring pieces 15a and 15b move outward in the radial direction due to the above-mentioned first movement control, the recess 157a of the cover ring piece 15a and the protrusion 157b of the cover ring piece 15b can be maintained in a vertically overlapping state. As a result, it is possible to suppress sputtered particles or particles, for example, passing between the cover ring pieces 15a and 15b and scattering downward.

According to the plasma treatment apparatus of the variation 1, the same effects as the plasma treatment apparatus 1 of the above-mentioned embodiment are also achieved.

### Second Embodiment

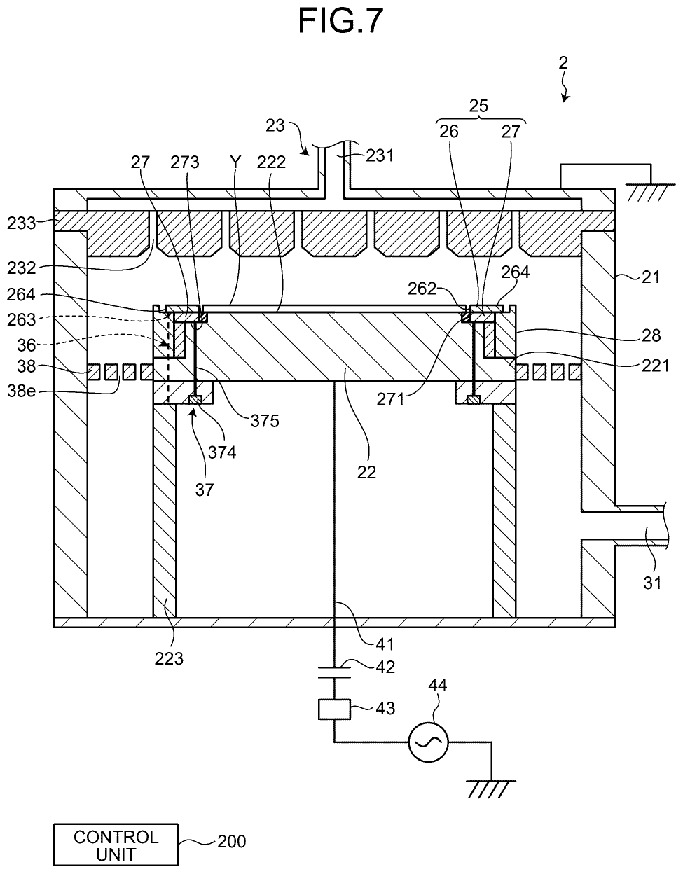

A second embodiment will be described with reference to FIGS. 7 to 11.

The plasma treatment apparatus 2 of the second embodiment differs from the first embodiment mentioned above in the device configuration and the type of substrate to be processed. In the following, the same components as those of the above-mentioned embodiment are denoted by the same reference numerals, and the description thereof may be omitted.

FIG. 7 is a cross-sectional view schematically illustrating an example of the overall configuration of a plasma treatment apparatus 2 according to the second embodiment. It should be noted that for ease of explanation, FIG. 7 may also illustrate components that are not included in the same cross section as other configurations, such as a first moving mechanism 36.

The substrate Y, which is the processing target of the plasma treatment apparatus 2 of the second embodiment, is formed with an underlayer film to be etched and a resist film acting as a mask on the underlayer film. The plasma treatment apparatus 2 of the second embodiment is configured as an etching device that performs etching process of the underlayer film using the resist film as a mask. In the present embodiment, the etching process is an example of plasma treatment.

As illustrated in FIG. 7, the plasma treatment apparatus 2 includes a treatment chamber 21 and a control unit 200.

The treatment chamber 21 is a housing configured to be able to accommodate the substrate Y to be processed.

A stage 22 is disposed inside the treatment chamber 21. The stage 22 is supported on a support part 223 that protrudes vertically upward in a cylindrical shape from the bottom wall in the vicinity of the center of the treatment chamber 21. The stage 22 includes a placement surface 222 on which a substrate Y can be placed. The substrate Y that has been loaded into the treatment chamber 21 is placed on the placement surface 222 with its front surface facing upward. In addition, the stage 22 includes a flange-shaped part 221 on its periphery.

A power supply line 41 that supplies radio frequency power is connected to the stage 22. A blocking capacitor 42, a matching unit 43, and a radio frequency power supply 44 are connected to the power supply line 41. Radio frequency power with a predetermined frequency is supplied from the radio frequency power supply 44 to the stage 22. That is, the stage 22 functions as a lower electrode.

A plasma generator 23 that generates plasma is provided above the stage 22. The plasma generator 23 includes a gas supply port 231 provided in the vicinity of the upper part of the treatment chamber 21, and a shower head 233 provided below the gas supply port 231.

A gas supply device (not illustrated) is connected to the gas supply port 231 via pipes, and the treatment gas used during the etching process is supplied.

The shower head 233 functions as an upper electrode. The shower head 233 is provided with gas flow paths 232 that penetrate the plate in the thickness direction. Treatment gas supplied from the gas supply port 231 is introduced into the treatment chamber 21 via the gas flow paths 232. When a radio frequency voltage is applied to the stage 22, which is the lower electrode, with the shower head 233, which is the upper electrode, grounded, plasma is generated above the stage 22.

A baffle plate 38 is provided between the side wall of the treatment chamber 21 and the stage 22. The baffle plate 38 includes gas outlet holes 38e that penetrate the plate in the thickness direction.

A gas evacuation port 31 is provided in the treatment chamber 21 below the baffle plate 38. A vacuum pump (not illustrated) is connected to the gas evacuation port 31 through a pipe. The vacuum pump can exhaust the atmosphere inside the treatment chamber 21.

An edge ring 25 is disposed around the substrate Y placed on the placement surface 222. The edge ring 25 includes a middle ring 27 that is disposed above the flange-shaped part 221 of the stage 22, and a top ring 26 that is disposed above the middle ring 27 so as to overlap with the middle ring 27. The top ring 26 and middle ring 27 are both annular members comprising a material such as quartz or silicon. It should be noted that the material included in the top ring 26 or middle ring 27 is not limited thereto. The top ring 26 has the function of adjusting the electric field (outermost sheath distribution) applied to the peripheral part of the substrate Y during etching process of the substrate Y so that it is not deflected in the vertical direction perpendicular to the surface of the substrate Y.

The top ring 26 is disposed such that an end surface 262, which faces radially inward, vertically overlaps with an end surface 271, which faces radially inward of the middle ring 27. In addition, the radial width of the top ring 26 is greater than the radial width of the middle ring 27. Therefore, the top ring 26 protrudes radially outward beyond the middle ring 27. The end surface 262 is an example of the end.

The base ring 28 is disposed below the outer end 264 of the top ring 26. The base ring 28 is also an annular member made of a material such as quartz or silicon.

In addition, the top ring 26 is divided in the circumferential direction. Although details will be described later, each top ring piece is connected to a first moving mechanism 36 at its lower surface 263. The first moving mechanism 36 penetrates the base ring 28 and is connected to the support part 223 of the stage 22. The first moving mechanism 36 moves each top ring piece in the radial direction of the substrate Y in accordance with instructions from the control unit 200. This moves the top ring 26 to a position at which at which the top ring 26 is concentric with the substrate Y.

In addition, the middle ring 27 is connected to the second moving mechanism 37 at its lower surface 273. The second moving mechanism 37 includes an actuator 374 disposed on the support part 223, and a pin 375 that penetrates the stage 22 from the actuator 374. The pin 375 is in contact with the lower surface 273 of the middle ring 27. The pin 375 is configured to be movable up and down by the operation of the actuator 374. The second moving mechanism 37 moves the middle ring 27 and the top ring 26 disposed above the middle ring 27 in the vertical direction by moving the pin 375 up and down in accordance with instructions from the control unit 200.

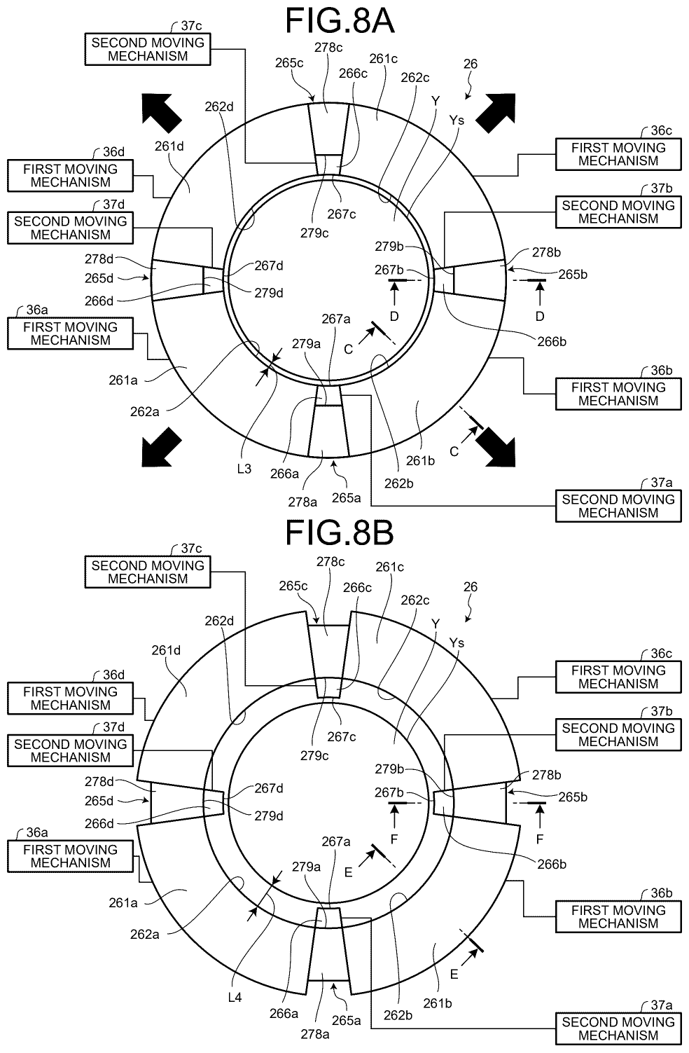

FIGS. 8A and 8B are top views illustrating a detailed configuration of the top ring 26 included in the plasma treatment apparatus 2 according to the second embodiment. For ease of explanation, FIGS. 8A and 8B also illustrate the substrate Y placed on the placement surface 222.

FIG. 8A is a top view illustrating a state where the top ring 26 is disposed at a reference position before it moves in the radial and vertical directions. In the present embodiment, the reference position is a position where the end surface 262 of the top ring 26 faces the end Ys of the substrate Y with a distance L3 provided therebetween. On the other hand, FIG. 8B is a top view illustrating a state where the end surface 262 of the top ring 26 faces the end Ys of the substrate Y with a distance L4 provided therebetween due to the top ring 26 moving in the radial and vertical directions.

As illustrated in FIG. 8A, the top ring 26 includes four first top ring pieces 261a to 261d arranged in the circumferential direction, and four second top ring pieces 265a to 265d arranged alternately in the circumferential direction with the first top ring pieces 261a to 261d. The first top ring pieces 261a to 261d are examples of first annular member pieces, and the four second top ring pieces 265a to 265d are examples of second annular member pieces. In addition, the top ring 26 is also an example of a third annular member.

The first top ring pieces 261a to 261d are arranged at predetermined intervals around the substrate Y placed on the placement surface 222. The first top ring pieces 261a to 261d include end surfaces 262a to 262d facing inward, respectively. In FIG. 8A, the end surfaces 262a to 262d face the end Ys of the substrate Y with a distance L3 provided therebetween. The end surfaces 262a to 262d are part of the end surface 262 of the top ring 26. The first top ring pieces 261a to 261d are connected to first moving mechanisms 36a to 36d, respectively.

It should be noted that hereinafter, part of the top ring 26 including the first top ring pieces 261a to 261d divided in the circumferential direction may be referred to as the first top ring 261.

As illustrated in FIG. 8B, the first moving mechanisms 36a to 36d move the first top ring 261 to a position at which the first top ring 261 is concentric with the substrate Y by moving the respective first top ring pieces 261a to 261d in the radial direction of the substrate Y. This enables the end Ys of the substrate Y to face the end surfaces 262a to 262d, for example, with a distance L4 provided therebetween.

Among the first top ring pieces 261a to 261d, the second top ring pieces 265a to 265d are arranged between adjacent first top ring pieces in the circumferential direction. That is, the first top ring pieces 261a to 261d and the second top ring pieces 265a to 265d are arranged alternately in the circumferential direction.

As illustrated in FIG. 8A, the second top ring pieces 265a to 265d are radially divided into movable parts 266a to 266d and stationary parts 278a to 278d, respectively.

The movable parts 266a to 266d are the parts arranged inside the radial direction. The movable parts 266a to 266d are connected to the second moving mechanisms 37a to 37d, respectively. The movable parts 266a to 266d are configured to move in the vertical direction by the second moving mechanisms 37a to 37d. In addition, the movable parts 266a to 266d include first surfaces 267a to 267d that face radially inward. The first surfaces 267a to 267d are arranged at positions spaced apart from the end Ys of the substrate Y by a distance L3. The first surfaces 267a to 267d are part of the end surface 262 of the top ring 26.

The stationary parts 278a to 278d are arranged outside the movable parts 266a to 266d. The stationary parts 278a to 278d include second surfaces 279a to 279d facing radially inward. The second surfaces 279a to 279d are arranged at positions spaced apart from the end Ys of the substrate Y by a distance L4 that is longer than the distance L3.

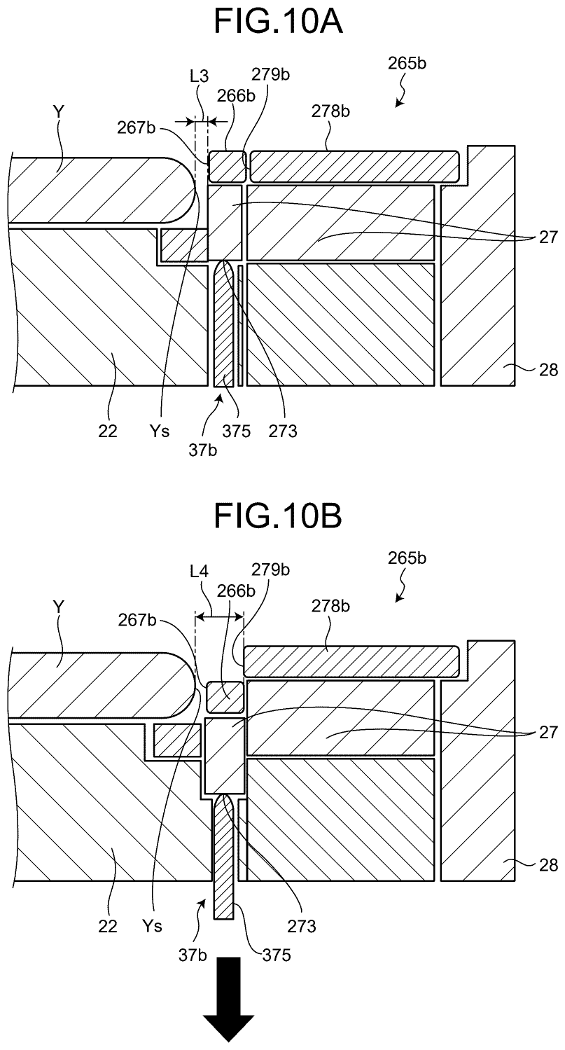

Details are described below with reference to FIGS. 10A and 10B, but when the movable parts 266a to 266d are moved downward from the reference position by the second moving mechanisms 37a to 37d, the second surfaces 279a to 279d of the stationary parts 278a to 278d are exposed and the second surfaces 279a to 279d face the end Ys of the substrate Y. That is, the second surfaces 279a to 279d can also become part of the end surface 262 of the top ring 26.

In addition, as described above, the middle ring 27 (see FIG. 7) is disposed below the top ring 26 so as to overlap with each other. Although not illustrated, the middle ring 27 is also divided in the thickness direction at positions that overlap in the vertical direction with the dividing positions in the circumferential and radial directions of the top ring 26. This enables the top ring 26 and middle ring 27 to be partly interlocked.

It should be noted that hereinafter, the part of the top ring 26 including the second top ring pieces 265a to 265d may be referred to as the second top ring 265.

The control unit 200 controls each unit of the plasma treatment apparatus 2. The hardware configuration of the control unit 200 is similar to that of the control unit 100, and therefore a description thereof will be omitted here. In the present embodiment, the control unit 200 controls each unit mentioned above to perform the etching process on the substrate Y. In addition, for example, the control unit 200 performs a first movement control for moving the first top ring 261 to a position at which the first top ring 261 is concentric with the substrate Y by instructing the first moving mechanism 36. In addition, for example, the control unit 200 performs a second movement control for moving the movable parts 266a to 266d of the second top ring 265 in the vertical direction by instructing the second moving mechanisms 37a to 37d.

As described above, the top ring 26 has the function of adjusting the electric field (outermost sheath distribution) applied around the periphery of the substrate Y when the etching process of the substrate Y is performed. Adjusting the outermost sheath distribution suppresses oblique incidence of ions onto the peripheral part of the substrate Y, and as a result, more uniform etching process can be achieved at the outer periphery and center of the substrate Y. However, the outermost sheath distribution may vary depending on the type of the underlying film and the shape of the pattern. Therefore, it is necessary to adjust the outermost sheath distribution depending on the type of the underlying film and the shape of the pattern. The outermost sheath distribution can be adjusted by changing the horizontal distance between the end Ys of the substrate Y and the end surface 262 of the top ring 26.

For example, the operator determines the optimal position of the top ring 26 with respect to the end Ys of the substrate Y for each type of underlying film and pattern shape, and registers this in advance in a recipe as an etching condition. The recipe is stored in the storage unit of the control unit 200. When the recipe is loaded, the control unit 200 executes the first and second movement controls in accordance with the etching conditions registered in the recipe. This makes it possible to obtain an optimal outermost sheath distribution in accordance with the type of underlying film and the shape of the pattern.

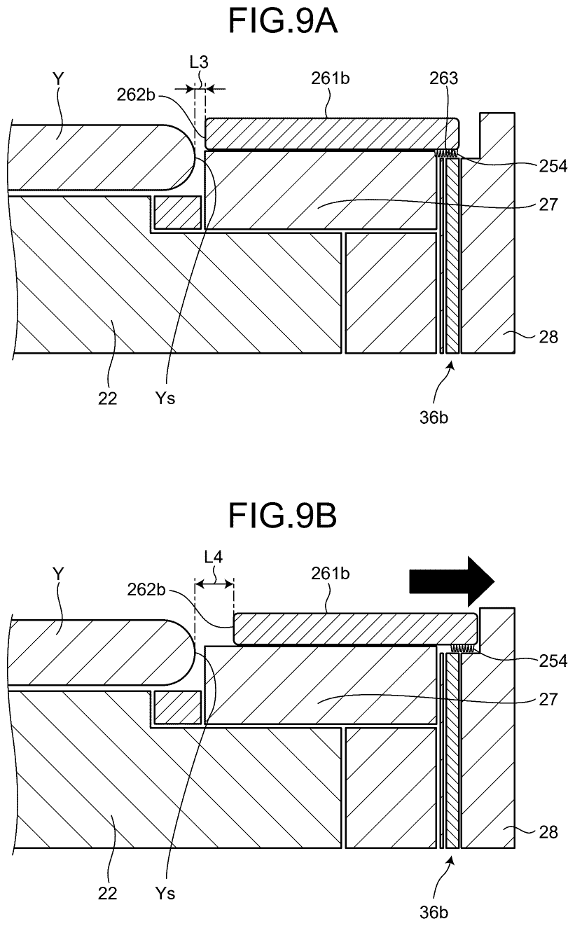

Here, the flows of the first and second movement control by the control unit 200 will be described with reference to FIGS. 9A to 9B and FIGS. 10A to 10B.

FIGS. 9A and 9B are diagrams illustrating the procedure of the first movement control in the plasma treatment apparatus 2 according to the second embodiment. FIG. 9A is a cross-sectional view illustrating the state in the vicinity of the first top ring 261 taken along line CC in FIG. 8A. On the other hand, FIG. 9B is a cross-sectional view illustrating the state in the vicinity of the first top ring 261 taken along line EE in FIG. 8B.

As illustrated in FIG. 9A, a rack gear 254 is provided on the lower surface 263 of the first top ring piece 261b. The rack gear 254 meshes with the upper end of the first moving mechanism 36b extending through the base ring 28. It should be noted that the first moving mechanism 36b has a configuration corresponding to the first moving mechanism 16 described with reference to FIGS. 3A and 3B, so a detailed description will be omitted here.

For example, when the second condition is registered in the recipe as the etching condition, the control unit 200 controls the first moving mechanism 36b to place the first top ring piece 261b at the reference position, as illustrated in FIG. 9A. At the reference position, the end surface 262b of the first top ring piece 261b and the end Ys of the substrate Y face each other with a distance L3 in the horizontal direction provided therebetween.

On the other hand, for example, when a first condition is registered in the recipe as an etching condition, the control unit 200 controls the first moving mechanism 36b to move the first top ring piece 261b outward in the radial direction, as illustrated in FIG. 9B. This relatively increases the horizontal distance between the end surface 262b of the first top ring piece 261b and the end Ys of the substrate Y, and makes it possible to face each other, for example, with a distance L4 provided therebetween.

FIGS. 10A and 10B are diagrams illustrating the procedure of the second movement control in the plasma treatment apparatus 2 according to the second embodiment. Specifically, FIG. 10A is a cross-sectional view illustrating the state in the vicinity of the second top ring 265 taken along line DD in FIG. 8A. FIG. 10B is a cross-sectional view illustrating the state in the vicinity of the second top ring 265 taken along line FF in FIG. 8B.

A pin 375 of the second moving mechanism 37b is in contact with the lower surface 273 of the middle ring 27. The middle ring 27 overlaps in the vertical direction with the movable part 266b of the second top ring piece 265b. By the pin 375 moving up and down, the movable part 266b moves in the vertical direction in conjunction with the middle ring 27.

For example, when a second condition is registered in the recipe as an etching condition, as illustrated in FIG. 10A, the control unit 200 controls the second moving mechanism 37b to place the movable part 266b at a first height position as a reference position. The first height position is a height position where a first surface 267b of the movable part 266b faces the end Ys of the substrate Y. At the first height position, the first surface 267b of the movable part 266b faces the end Ys of the substrate Y with a distance L3 provided therebetween.

For example, when a first condition is registered in the recipe as an etching condition, as illustrated in FIG. 10B, the control unit 200 controls the second moving mechanism 37b to move the movable part 266b to a second height position lower than the first height position. When the movable part 266b moves to the second height position, the second surface 279b of the stationary part 278b is exposed, and the second surface 279b faces the end Ys of the substrate Y. Accordingly, the second top ring piece 265b faces the end Ys of the substrate Y with a distance L4 provided therebetween.

### Manufacturing Method of a Semiconductor Device

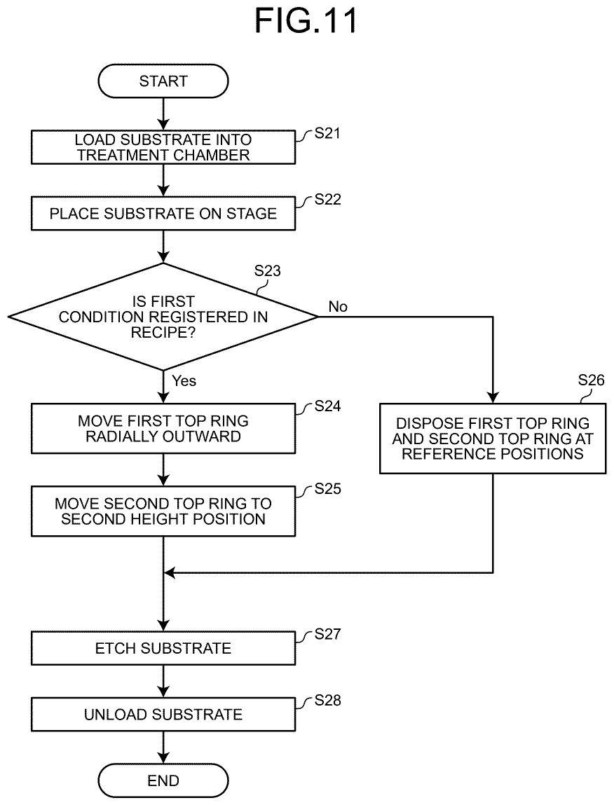

In FIG. 11, the procedure of the etching process as part of the manufacturing method of the semiconductor device of the second embodiment will be described.

FIG. 11 is a flow chart illustrating an example of a procedure for etching process in the plasma treatment apparatus 2 according to the second embodiment. The above-mentioned first and second movement controls are performed as part of the etching process.

On the surface of the substrate Y to be processed by the plasma treatment apparatus 2 of the second embodiment, for example, an underlayer film to be etched and a resist film serving as a mask are formed.

When the recipe is loaded into the plasma treatment apparatus 2, the control unit 200 controls a transport arm (not illustrated) to load the substrate Y into the treatment chamber 21 (S21). Then, the control unit 200 controls the transport arm to place the substrate Y on the placement surface 222 of the stage 22 (S22). The top ring 26 and middle ring 27 are disposed around the substrate Y. At this time, the first top ring 261 and the second top ring 265 are disposed at, for example, a reference position.

The control unit 200 determines whether or not the first condition is registered in the loaded recipe (S23).

When the control unit 200 determines that the first condition is registered in the recipe (S23: Yes), the control unit 200 changes the horizontal distance between the first top ring 261 and the end Ys of the substrate Y by controlling the first moving mechanisms 36a to 36d to move the first top ring 261 radially outward (S24). In addition, the control unit 200 changes the horizontal distance between the second top ring 265 and the end Ys of the substrate Y by controlling the second moving mechanisms 37a to 37d to move the movable parts 266a to 266d of the second top ring 265 to a second height position (S25).

It should be noted that the processing of S23 and S24 may be performed at any timing before the processing of S25 is started. In addition, when the control unit 200 determines that the first condition is not registered in the recipe (S23: No), namely, for example, when the control unit 200 determines that the second condition is registered in the recipe, the control unit 200 controls the first moving mechanisms 36a to 36d and the second moving mechanisms 37a to 37d to dispose the first top ring 261 and the second top ring 265 at their respective reference positions (S26).

The control unit 200 controls the plasma generator 23 to generate plasma and etch the substrate Y (S27).

When the etching of the substrate Y is completed, the control unit 200 controls the transport arm (not illustrated) to unload the substrate Y from the treatment chamber 21 (S28). As described above, the etching process of the second embodiment is completed.

### Generalization

The top ring 26 provided in the plasma treatment apparatus 2 of the second embodiment includes a first top ring 261 divided in the circumferential direction, and a second top ring 265 provided alternately with the first top ring 261 in the circumferential direction. The first top ring 261 is configured to be movable in the radial direction to a position at which the first top ring 261 is concentric with the substrate Y. The second top ring 265 is divided into a movable part 266 including a first surface 267 facing inward in the radial direction, and a stationary part 278 disposed outside the movable part 266 and including a second surface 279 facing inward in the radial direction. The movable part 266 is configured to be movable in a direction intersecting with the substrate surface of the substrate Y to a first height position or a second height position lower than the first height position. In addition, the stationary part 278 is fixed at the first height position.

The plasma treatment apparatus 2 of the second embodiment executes a first movement control to move the first top ring 261 to a position at which the first top ring 261 is concentric with the substrate Y. This changes the distance between the end Ys of the substrate Y and the first top ring 261. In addition, by moving the movable part 266 of the second top ring 265 to a first height position or a second height position, a second movement control is executed to cause either the first surface 267 or the second surface 279 outside the first surface 267 to face the end Ys of the substrate Y. This changes the distance between the end Ys of the substrate Y and the second top ring 265.

In this manner, by executing the first and second movement controls for the first top ring 261 and the second top ring 265, respectively, the horizontal distance between the end Ys of the substrate Y and the end of the top ring 26 is relatively changed. Since this adjusts the outermost peripheral sheath distribution, it is possible to perform the etching process more uniformly within the surface of the substrate Y. As a result, for example, pattern shape defects at the outer periphery of the substrate Y can be suppressed.

In addition, the outermost sheath distribution differs depending on the type of substrate Y. Etching conditions that define the optimal distance between the substrate Y and the second top ring 265 for each type of substrate Y are registered in advance in the recipe. When the recipe is loaded, the control unit 200 determines whether to execute the first and second movement controls based on the etching conditions registered in the recipe. Since the outermost sheath distribution is adjusted individually depending on the type of substrate Y, etching process can be performed stably on various substrates.

While certain embodiments have been described, these embodiments have been presented by way of example only, and are not intended to limit the scope of the present disclosure. Indeed, the novel embodiments described herein may be embodied in a variety of other forms; moreover, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma treatment apparatus comprising:
a treatment chamber capable of processing a substrate;
a stage on which the substrate is to be placed, the stage being provided inside the treatment chamber;
a plasma generator configured to generate plasma above the stage on which the substrate is placed;
a first annular member disposed around the substrate placed on the stage, the first annular member being divided into first annular member pieces arranged in a circumferential direction; and
a first moving mechanism configured to
move the first annular member to a position at which the first annular member is concentric with the substrate, the first annular member being moved by moving each of the first annular member pieces in a radial direction of the substrate, and
relatively change a horizontal distance between an end of the substrate and an inner end of the first annular member.

2. The plasma treatment apparatus according to claim 1, wherein adjacent pieces among the first annular member pieces arranged in the circumferential direction are engaged with each other at respective ends by a labyrinth structure.

3. The plasma treatment apparatus according to claim 2, wherein
the first annular member pieces each include a rack gear arranged in a radial direction,
the first moving mechanism includes a pinion gear connected to a rotary shaft extending in a circumferential direction, the pinion gear being rotatable in the radial direction around the rotary shaft, and
the first annular member pieces are each configured to move in the radial direction by meshing the rack gear with the pinion gear.

4. The plasma treatment apparatus according to claim 1, further comprising:
a target member disposed at an upper part inside the treatment chamber; and
a control device configured to
determine a movement amount of the first annular member based on a target life indicating a consumption amount of the target member sputtered by the plasma, and
control the first moving mechanism based on the movement amount.

5. The plasma treatment apparatus according to claim 4, wherein the control device is configured to perform the determination of the movement amount of the first annular member by
determining a thickness of a sputtered particle layer corresponding to the target life based on a table representing a correspondence between the target life and a thickness of the sputtered particle layer formed on the first annular member by sputtered particles from the target member, and
setting the thickness of the sputtered particle layer as the movement amount of the first annular member.

6. The plasma treatment apparatus according to claim 1, further comprising:
a target member disposed at an upper part inside the treatment chamber; and
an anti-deposition plate provided at least either on a side of the first annular member or below the first annular member, the anti-deposition plate being configured to prevent sputtered particles from the target member sputtered by the plasma from being deposited in the treatment chamber.

7. The plasma treatment apparatus according to claim 1, wherein the number of the first annular member pieces constituting the first annular member is four.

8. The plasma treatment apparatus according to claim 1, further comprising:
second annular member pieces arranged alternately with the first annular member pieces in the circumferential direction; and
a second moving mechanism configured to move each of the second annular member pieces in a direction intersecting with a substrate surface of the substrate, wherein
each of the second annular member pieces includes
a movable part including a first surface facing inward in the radial direction, the movable part being movable between a first height position where the first surface faces an end of the substrate and a second height position lower than the first height position, and
a stationary part provided at the first height position outside the movable part, the stationary part including a second surface facing inward in the radial direction, and
the second moving mechanism is configured to relatively change a horizontal distance between the end of the substrate and the second annular member pieces by moving the movable part to either the first height position or the second height position to cause either the first surface or the second surface face the end of the substrate.

9. The plasma treatment apparatus according to claim 8, wherein
the plasma treatment apparatus is configured to be capable of performing an etching process on the substrate by the plasma, and
the plasma treatment apparatus further comprises a control device configured to, when the etching process is performed under a first condition,
control the second moving mechanism to cause the end of the substrate and the second surface of the stationary part to face each other by moving the movable part to the second height position, and
control the first moving mechanism to move the first annular member pieces radially outward of the substrate.

10. The plasma treatment apparatus according to claim 9, wherein the control device is configured to, when the etching process is performed under a second condition,
control the second moving mechanism to cause the end of the substrate and the first surface of the movable part to face each other by moving the movable part to the first height position, and
control the first moving mechanism to move the first annular member radially inward of the substrate.

11. The plasma treatment apparatus according to claim 8, wherein
the second moving mechanism includes a pin provided to be in contact with a middle ring, the middle ring overlapping with the movable part in a vertical direction, and
the movable part is configured to, when the pin moves up and down, move to either the first height position or the second height position in conjunction with the middle ring.

12. A manufacturing method of a semiconductor device, the manufacturing method comprising:
loading a substrate of the semiconductor device into a treatment chamber;
placing the substrate on a stage provided inside the treatment chamber;
disposing a first annular member around the substrate placed on the stage;
changing a horizontal distance between an end of the substrate and an inner end of the first annular member by moving the first annular member to a position at which the first annular member is concentric with the substrate; and
supplying plasma to the treatment chamber from a plasma generator provided at an upper part of the treatment chamber.

13. The manufacturing method according to claim 12, wherein
the first annular member is divided into first annular member pieces arranged in a circumferential direction, and
the manufacturing method further comprises engaging adjacent pieces among the first annular member pieces with each other at respective ends by a labyrinth structure.

14. The manufacturing method according to claim 12, wherein
the first annular member is divided into first annular member pieces arranged in a circumferential direction,
the manufacturing method further comprises
providing each one of the first annular member pieces with a rack gear arranged in a radial direction, and
providing a first moving mechanism connected to the first annular member pieces with a pinion gear, the pinion gear being connected to a rotary shaft extending in a circumferential direction and being rotatable in the radial direction around the rotary shaft,
the moving of the first annular member to the position at which the first annular member is concentric with the substrate is performed by
moving the first annular member pieces in the radial direction by meshing the rack gear with the pinion gear.

15. The manufacturing method according to claim 12, further comprising disposing a target member at an upper part inside the treatment chamber, wherein
the moving of the first annular member to the position at which the first annular member is concentric with the substrate includes
determining a movement amount of the first annular member based on a target life indicating a consumption amount of the target member sputtered by the plasma.

16. The manufacturing method according to claim 15, wherein the determining of the movement amount of the first annular member based on the target life includes
determining a thickness of a sputtered particle layer corresponding to the target life based on a table representing a correspondence between the target life and a thickness of the sputtered particle layer formed on the first annular member by sputtered particles from the target member, and
setting the thickness of the sputtered particle layer as the movement amount of the first annular member.

17. The manufacturing method according to claim 12, wherein
the disposing of the first annular member around the substrate includes
arranging first annular member pieces alternately with second annular member pieces in the circumferential direction, the first annular member pieces being obtained by dividing the first annular member,
each of the second annular member pieces includes
a movable part including a first surface facing inward in the radial direction, the movable part being movable between a first height position where the first surface faces an end of the substrate and a second height position lower than the first height position, and
a stationary part provided at the first height position outside the movable part, the stationary part including a second surface facing inward in the radial direction, and
the changing of the horizontal distance between the end of the substrate and the inner end of the first annular member includes
changing a horizontal distance between the end of the substrate and inner ends of the second annular member pieces by moving the movable part to either the first height position or the second height position to cause either the first surface or the second surface face the end of the substrate.

18. The manufacturing method according to claim 17, further comprising performing an etching process on the substrate by the plasma,
wherein the performing of the etching process includes, under a first condition,
controlling a second moving mechanism to cause the end of the substrate and the second surface of the stationary part to face each other by moving the movable part to the second height position, and
controlling a first moving mechanism to move the first annular member pieces radially outward of the substrate.

19. The manufacturing method according to claim 18, wherein the performing of the etching process includes, under a second condition,
controlling the second moving mechanism to cause the end of the substrate and the first surface of the movable part to face each other by moving the movable part to the first height position, and
controlling the first moving mechanism to move the first annular member radially inward of the substrate.

20. The manufacturing method according to claim 18, wherein
the second moving mechanism includes a pin provided to be in contact with a middle ring, the middle ring overlapping with the movable part in a vertical direction, and
the manufacturing method further comprises moving the pin up and down to move the movable part to either the first height position or the second height position in conjunction with the middle ring.
